(19) United States
(12) Patent Application Publication
(10) Pub. No.: US 2006/0032619 A1
(43) Pub. Date: Feb. 16, 2006

(54) Heat-radiating device with a guide cap

(76) Inventor: Jin-Yuan Yang, Wu Hai City (CN)

Correspondence Address: MOLEX INCORPORATED, 2222 WELLINGTON COURT, LISLE, IL, 60532, US

(21) Appl. No.: 11/204,127

(22) Filed: Aug. 15, 2005

(30) Foreign Application Priority Data
Aug. 13, 2004 (CN) 200420087951.9

(51) Int. Cl. B29C 47/88; H01L 23/467; F24H 3/02

(52) U.S. Cl. 165/120; 165/121

(57) ABSTRACT

A heat-radiating device with a guide cap includes a radiator, a fan and a guide cap over the fan. The radiator is fixed to a circuit board by using four fixing bolts mounted in four corners of its bottom to attach tightly with a top surface of an electronic element. The guide cap is a quadrate frame and in the middle of each of its four side walls protrudes outward an arc surface, the four arc surfaces form by means of surrounding a truncated-cone shaped air flow path with a large upper and a small lower, in each of four corner of bottom of the guide cap provides a lock hole and protrudes downward four barbs for buckling with the hooks of the fan. The guide cap can feed effectively a low temperature air flow to improve the radiating efficiency of the radiator. In addition, configuration of the guide cap is easy to screw the four fixing bolts so as to assemble the heat-radiating device to a circuit board, and thus the assembling is more convenient.

### FIELD OF THE INVENTION

The present invention relates to a heat-radiating device with a guide cap, and in particular, to a heat-radiating device with a guide cap, which has improved air flow guiding properties and is easy to assemble to a circuit board.

### BACKGROUND OF THE INVENTION

The conventional heat-radiating device of electronic elements, particularly a CPU, may be air-cooled by using a fan and a radiator, and the cooler air directed toward the radiator is fed by the axial flow fan. In the prior art, air passed through the radiator may quickly circulate back to the inlet position of the axial flow fan so that the air temperature closer to the electronic elements is higher and the axial flow fan can not blow the lower temperature air toward the radiator, thereby the radiating effect is reduced.

Chinese patent No. 03240567.7 proposes a heat-radiating device with an extending air flue which can feed a lower temperature air flow to avoid the short circuit of air flow and thus the radiating effect is improved. However, the designed extending air flue will take more upper space of two sides of the heat-radiating device since the outlet of each of the two sides has a bugle shape protruding outward to cause difficulty in assembling, especially, when the manufacturers of the heat-radiating device sell the whole heat-radiating device to the system assembling sellers and the system assembling sellers assemble it to a mainboard, the screw driver will be subject to the interference of the bugle-shaped outlet outside the extending air flue so that it is difficult to fasten the three fixing bolts adjacent to the two sides of the heat-radiating device, and even it needs to screw the fixing bolts after disassembling the extending air flue and then reset the extending air flue, thus the assembling is very inconvenient. Furthermore, the configuration of the air flow path in the middle of the extending air flue differs more from that of the round carrying air flow path of the radiating fan so that it is easy to result in an eddy flow during flowing of the air flow. Thus, improvements to the flow using a guide is desired.

### SUMMARY OF THE INVENTION

A major object of the present invention is to provide a heat-radiating device with a guide cap, which can avoid the air flow circulating in a short distance so that the axial flow fan can effectively feed a lower temperature air to through the radiator, while at the same time making it easier to fasten four fixing bolts for fixing the heat-radiating device when assembled to a circuit board.

To achieve the above object, the present utility model provides a heat-radiating device with a guide cap, including a radiator, a fan, and a guide cap, the radiator is fastened to a circuit board by using four fixing bolts mounted in four corners of its bottom for attaching tightly with the top surface of an electronic element. The fan is an axial flow fan, in the center of which is provided with a round carrying, air path and one side of which is fixed to the radiator. The guide cap is fixed correspondingly to the other side of the fan and is a quadrate frame, in the middle of each of four side walls protrudes outward an arc surface to form by means of surrounding an air flow path with a truncated-cone shape having a large upper and a small lower.

The present invention has the following advantageous effects: in the middle of the side walls of the guide cap protrudes outward an arc surface so that there is no interference of screwing the fixing bolts for fixing the heat-radiating device while the area of wind inlet is increased, and thus the assembling is more convenient. Also, the arc surfaces form by means of surrounding an air flow path with a truncated-cone shape having a large upper and a small lower, that can match better with the round carrying wind path of the fan to reduce the eddy flow produced by the air flow and thus increase the heat dissipating effect of the radiator.

### BRIEF DESCRIPTION OF THE DRAWINGS

The organization and manner of the structure and operation of the invention, together with further objects and advantages thereof, may best be understood by reference to the following description taken in connection with the accompanying drawings wherein like reference numerals identify like elements in which:

FIG. 1 is an isometric exploded view of the heat-radiating device with a guide cap according to the utility model;

FIG. 2 is an isometric combined view of the heat-radiating device with a guide cap according to the utility model;

FIG. 3 is a top view of the heat-radiating device with a guide cap according to the utility model;

### DETAILED DESCRIPTION OF THE DISCLOSED EMBODIMENT

While this invention may be susceptible to embodiment in different forms, there is shown in the drawings and will be described herein in detail, a specific embodiment with the understanding that the present disclosure is to be considered an exemplification of the principles of the invention, and is not intended to limit the invention to that as illustrated.

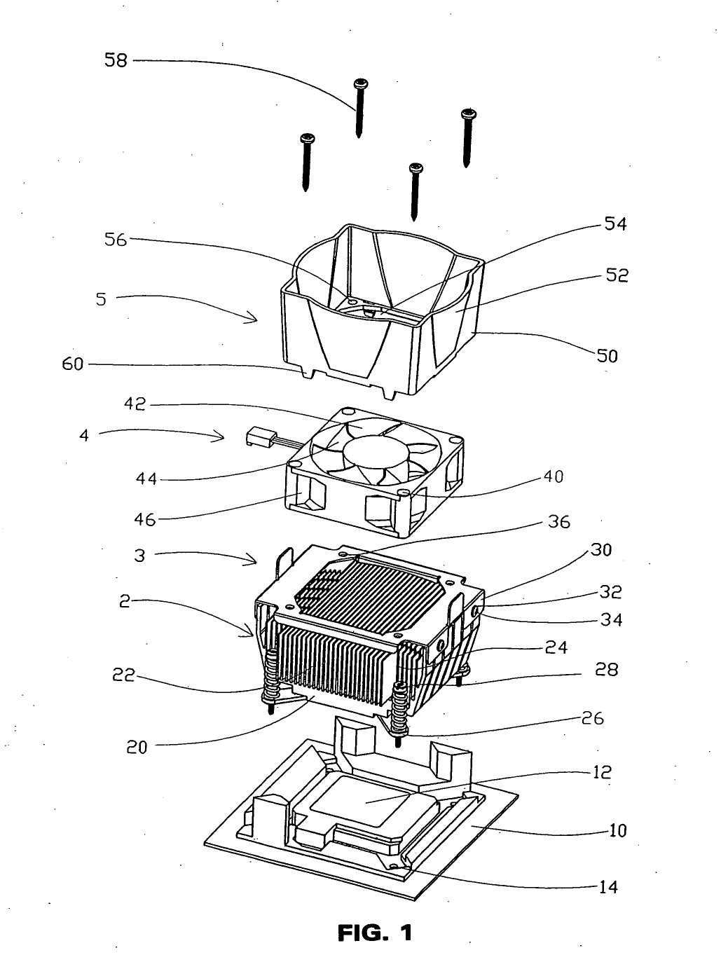

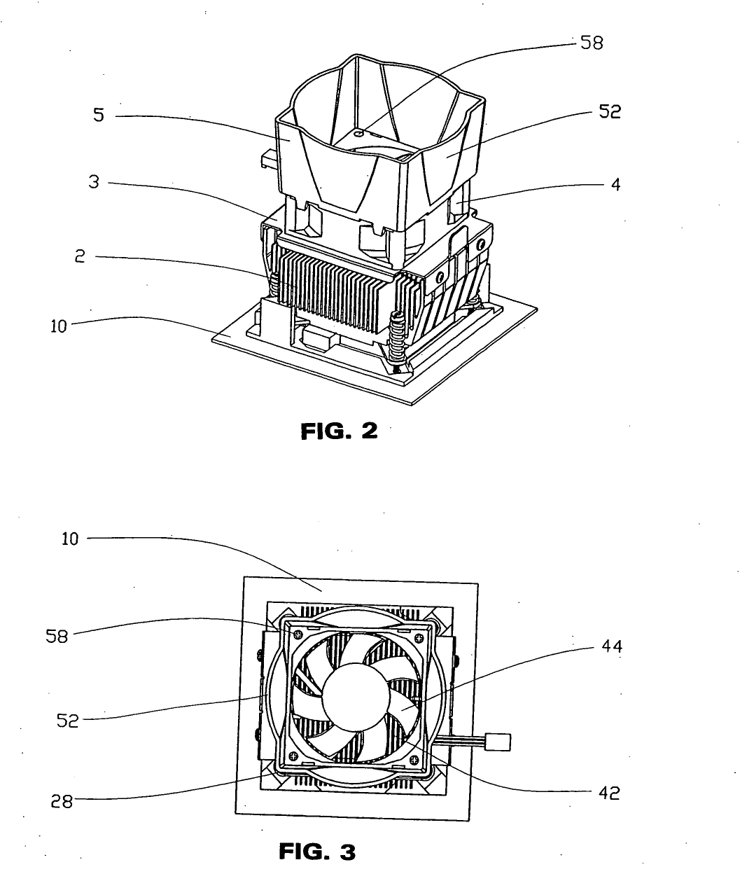

Referring to FIG. 1 to FIG. 3, a heat-radiating device with a guide cap includes a radiator 2, a fan fixing frame 3, a fan 4 and a guide cap 5 provided in the direction of the air inlet of the fan 4.

The radiator 2 includes a base 20 and a plurality of fins 22 extending upward from the base 20. The radiator 2 can be mounted on a circuit board 10 for radiating heat from the CPU 12 mounted on the circuit board 10 to ensure its normal operation. In each of four corners of the radiator 2 is provided with a notch 24. On the bottom of the radiator 2 is provided with two fixing tabs 26, each of two ends of each fixing tab 26 penetrates a fixing bolt 28. These fixing bolts 28 are mounted correspondingly in the notches 24 of the radiator 2 and are screwed into the four bolt holes 14 of the circuit board 10 or the bolt holes on the side plate of the casing (not shown in Figures) to the back of the circuit board 10 so that the radiator 2 may be fastened reliably to the circuit board 10 and to attach tightly with the top surface of the CPU 12.

Each of two ends of the fan fixing frame 3 bends downward to form two buckling sheets 30 on which provides a through hole 32. Two sides of the radiator 2 provide four bolt holes (not shown in Figures) corresponding to the through holes 32 of the buckling sheets 30. A fixing bolt 34 passes through the through hole 32 to be fastened into the bolt hole so that the fan fixing frame 3 is mounted and fastened to the radiator 2. In each of four corners of the fan fixing frame 3 is provided a lock hole 36, and in the center of the fan fixing frame is provided an opening corresponding to the fan 4 to ensure passing through of the air flow smoothly.

The fan 4 is an axial flow fan, each of four corners of which provides a through hole 40 corresponding to the lock holes 36. In the center of the fan provides a round carrying air flow path 42 and a flabellum 44.

The guide cap 5 is substantially a quadrate frame, in the middle of each of four side walls 50 protrudes an arc surface 52 which locates on the concentric circle with the center of the fan 4 serving as a center thereof to form by surrounding an air flow path 54 with a substantial truncated-cone shape having a large upper and a small lower. In operation, the cooling air flow is fed from the air flow path 54 of the guide cap 5 and is directed toward the radiator 2 after passing through the air flow path 42 of the fan 4. The truncated-cone shaped air flow path 54 can match better with the round air flow path 42 of the fan 4 to flow smoothly, thereby reducing the eddy flow, and the heat dissipating efficiency is improved. Whereas the disclosed embodiment shows an arc surface on each of the side walls, it is contemplated that there may be instances where it is not necessary or desirable to have an arc surface on each of the side walls.

In each of four corners of the bottom of the guide cap 5 close to the fan 4 is provided a lock hole 56. A bolt 58 passes through the lock hole 56 of the guide cap 5 and the through hole 40 of the fan 4 to be fastened into the lock hole 36 of the fan fixing frame 3 so that both the fan 4 and the guide cap 5 are fastened to the radiator 2. The guide cap 5 also includes four barbs 60 at a lower surface of the guide cap. The fan 4 provides a plurality of grooves 46 corresponding to the barbs 60, and the barbs 60 are hooked correspondingly into the grooves 46 so that the guide cap 5 connects with the fan 4 more reliably.

The guide cap 5 protrudes outward as a result of the arc surface 52 in the middle of each of four side walls 50 so that the area of wind inlet is enlarged. In addition, this guide cap 5 does not cover the space over the fixing bolts 28 in four corners of the radiator 2, thus it is more suitable to adap6t for the narrow assembling surroundings is in the computer casing (not shown in Figures). Thus, assembling the heat-radiating device of the present invention is more convenient.

The illustrated embodiment is only one implemented mode of the guide cap 5. Also, the guide cap 5 can be used in a side blow heat-radiating device, that is, both the fan 4 and the guide cap 5 are mounted to one side of the radiator 2 so that the cooling air flow is fed from one side of the radiator 2 and is blown out from the other side to take away the heat, and the improved heat dissipating efficiency can be obtained due to feeding a lower temperature air flow and avoiding the short circuit of air flow occurring.

While a preferred embodiment of the invention is shown and described, it is envisioned that those skilled in the art may devise various modifications without departing from the spirit and scope of the foregoing description and the appended claims.

What is claimed is:

1. A heat-radiating device, comprising a radiator, a fan and a guide cap, wherein the guide cap is fastened to the fan and wherein the guide cap is a quadrate frame having four sidewalls and wherein an air flow path is provided in a center of the quadrate frame and wherein the middle of at least one of the four sidewalls of the guide cap protrudes outwardly in an arc shaped surface.

2. The heat-radiating device of claim 1, wherein a plurality of the four sidewalls of the guide cap protrudes outwardly in an arc shaped surface.

3. The heat-radiating device of claim 1, wherein the guide cap includes a plurality of barbs for buckling to the fan.

4. The heat-radiating device of claim 3, further including a fan fixing frame which is mounted and fixed to the radiator.

5. The heat-radiating device of claim 1, wherein each of the four side walls of the guide cap protrudes outwardly in an arc shaped surface.

6. The heat-radiating device of claim 1, wherein the four arc surfaces are located on a concentric circle that corresponds to a center of the fan serving as its center thereof.

7. The heat-radiating device of claim 6, wherein the four arc surfaces surround to form a truncated-cone shaped air flow path.

8. The heat-radiating device of claim 1, wherein the fan is an axial flow fan, the cooling air flow is fed through the guide cap and is directed towards the radiator after passing through the air flow path of the fan.
